(19) United States
(12) Patent Application Publication
(10) Pub. No.: US 2018/0323130 A1
(43) Pub. Date: Nov. 8, 2018

(54) ADHESIVE POLYMER THERMAL INTERFACE MATERIAL WITH SINTERED FILLERS FOR THERMAL CONDUCTIVITY IN MICRO-ELECTRONIC PACKAGING

(71) Applicant: Intel Corporation, Santa Clara, CA (US)

(72) Inventors: Boxi LIU, Chandler, AZ (US); Syadwad JAIN, Chandler, AZ (US); Jelena CULIC-VISKOTA, Gilbert, AZ (US); Nachiket R. RARAVIKAR, Gilbert, AZ (US); James C. MATAYABAS, Jr., Gilbert, AZ (US)

(21) Appl. No.: 15/771,025

(22) PCT Filed: Dec. 22, 2015
(86) PCT No.: PCT/US2015/067373

§ 371 Date: Apr. 25, 2018

(51) Int. Cl. H01L 23/373; C08K 3/08; C08L 83/04; C08G 77/12; H01L 23/367; C09K 5/06; H01L 23/00

(52) U.S. Cl. CPC H01L 23/3737; C08K 3/08; C08L 83/04; C08G 77/12; H01L 2224/83862; C09K 5/063; H01L 24/83; H01L 2224/8384; H01L 23/3672

(57) ABSTRACT

An adhesive polymer thermal interface material is described with sintered fillers for thermal conductivity in micro-electronic packaging. Embodiments include a polymer thermal interface material (PTIM) with sinterable thermally conductive filler particles, a dispersant, and a silicone polymer matrix.

### FIELD

The present description relates to thermal adhesives for micro-electronic and mechanical packaging and in particular to thermal adhesives that combine polymers with a conductive filler.

### BACKGROUND

In the assembly of semiconductor packages, greases, fillers and adhesives are used to attach covers and heat sinks to completed dies and to attach different parts of a package to each other. Because a semiconductor die heats with use, the different parts of a package, including the die will expand and contract. Any adhesive must allow for this expansion and contraction. As a result, greases and polymers are often used between parts. On the other hand, heat must be conducted away from the die so that it does not overheat during use. Greases and polymers are very poor heat conductors, but most heat conductors do not accommodate expansion and contraction between parts of the package.

Thermal interface materials (TIMs) are used to attach heat spreaders to a die and to attach heat sinks to a package. TIMs are designed to balance adhesion, flexibility, heat conductance, thermal stability, ease of use, and cost, among other factors. A variety of different formulations have been developed for different applications that feature different characteristics.

A variety of different materials are used to attach the heat spreader to the die. Polymer TIM (PTIM) has been enhanced using Al fillers. Solder TIM (STIM) has been enhanced using Indium.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a diagram of a key components of a sinterable PTIM before sintering according to an embodiment of the invention.

FIG. 2 is a diagram of filler materials with a single metal according to an embodiment of the invention.

FIG. 3 is a diagram of filler materials with multiple metals according to an embodiment.

FIG. 4 is a diagram of an image of neck formation between sintering nanoparticles according to an embodiment.

FIG. 5 is a process flow diagram of forming a package using a sinterable thermal interface material according to an embodiment.

FIG. 6 is a diagram of metal filler particles of a sinterable thermal interface material before and after sintering according to an embodiment.

FIG. 7 is a diagram of a package formed using a sinterable thermal interface material according to an embodiment.

FIG. 8 is a diagram of an alternative package formed using a sinterable thermal interface material according to an embodiment.

FIG. 9 is a block diagram of a computing device incorporating a microelectronic package according to an embodiment of the invention.

### DETAILED DESCRIPTION

As described herein sinterable metal particles may be used as fillers in a PTIM (Polymer Thermal Interface Material) formulation. Such a PTIM may be dispensed in the same way as a traditional PTIM and the BLT (Bond Line Thickness) is determined by the maximum size of the filler particles. This PTIM may be cured in the same way as a traditional PTIM. When cured, instead of only curing the polymer matrix, the filler is also sintered. Sintering the filler increases the thermal conductivity of the PTIM. With the finally cured and processed package, the resulting cured filled PTIM has a low BLT and high thermal conductivity. This may also be referred to as a low thermal resistance.

Metal particles have been used as a filler for die attach pastes. These pastes attach the back side metallization of a die to a metal lead frame. A full metal bond is formed between these two metal surfaces after sintering. This full metal bond requires both surfaces to be metal and forms a very strong bond. In the event that one component is exposed to a different thermal load or has a different coefficient of thermal expansion, then there may be a large mechanical stress applied to the metal bond. With enough heat the bond or one of the components may crack. In practice when a die with a metallized back side is bonded to a metal plate, then the die cracks, destroying the die.

The sinterable PTIM as described herein sinters at low temperature, has a low modulus and has good adhesion. The fillers sinter at relatively low temperatures. In many cases, the temperature is less than the solder reflow temperature. This is valuable when the PTIM is applied after solder reflow. If the materials were to be heated above the solder reflow temperature, then the previous solder bond may be affected. A low modulus allows the PTIM to absorb thermal mechanical stresses in the package. This allows the package to go from a temperature colder than room temperature to a high operating temperature without damage to the die. Good adhesion to both the lid and die surfaces ensures that the package stays intact and that the thermal bond stays intact through many different thermal and physical stresses.

The TIM material described herein may be applied in microelectronic packaging not only as TIM1 (TIM between the die and the heat spreader), but also as the TIM between the package and the thermal plate or heat sink. It may also be used for other heat removal applications. With the described sinterable TIM, there are metal bonds between sintered filler particles after curing and sintering. The thermal resistance from filler particle to filler particle is therefore very low.

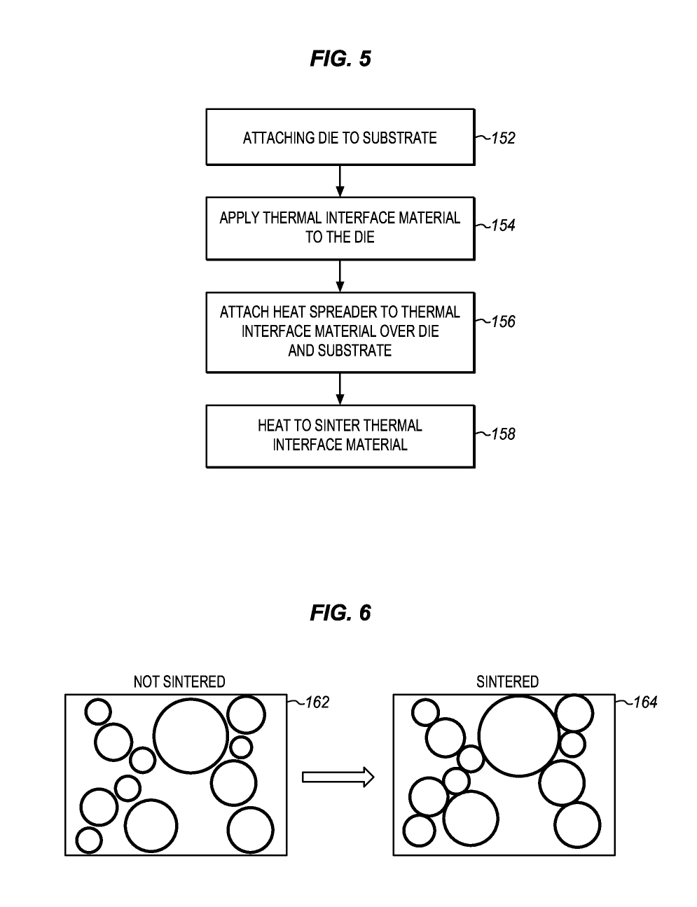

The thermal conductivity is increased as seen from the perspective of average filler size. The sintered filler particles are larger than the initial particles before sintering. The larger average filler size provides for a lower thermal resistance. In the described sinterable TIM, the average filler size is increased because multiple nanoparticles are sintered together. In addition nanoparticles are sintered to microparticles after the sintering process as shown in FIG. 5. TIM BLT on the other hand is determined by the maximum filler size before sintering. This allows there to be a small BLT together with high thermal conductivity.

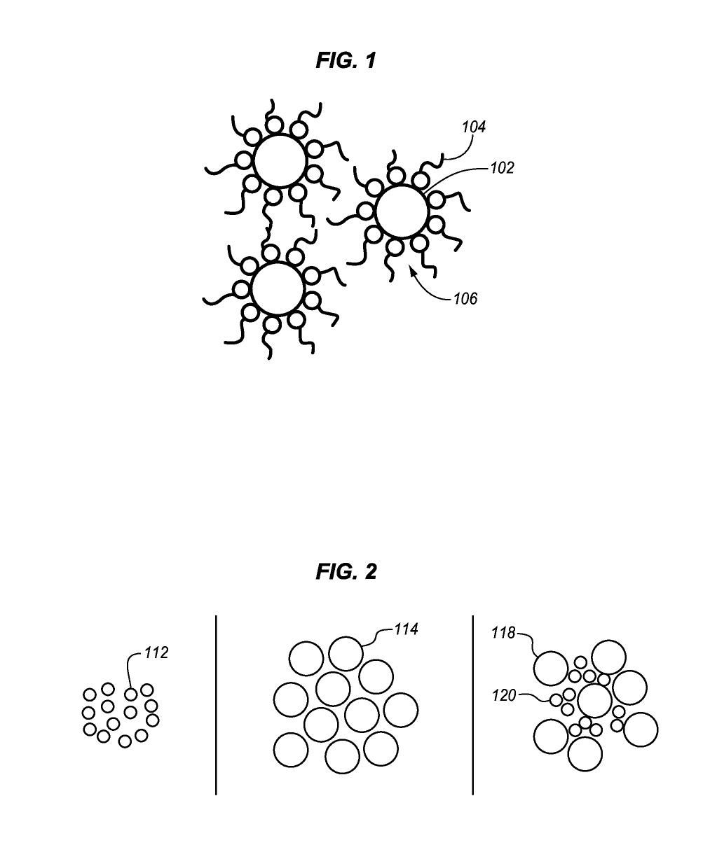

FIG. 1 is a diagram of a PTIM that has not been sintered to show three of the components in the described sinterable PTIM. These components include 1) sinterable metal particles 102 as fillers, 2) a dispersant 104, and 3) a polymer matrix 106. These components are combined to provide the intended properties. There may also be additional components to suit particular requirements for different applications.

The metal particles may be formed from several different metals. Some metal nanoparticles (such as Ag, Cu) have a tendency to sinter to form bigger particles at relatively low temperatures (such as below 300° C.). The formation of larger particles may be driven by surface tension so that no flux is required to cause the formation. Ag nanoparticles may sinter at temperatures as low as 160° C. This is also the curing temperature for certain polymer matrix materials. Cu nanoparticles can start sintering at about 300° C. This temperature may be lowered by controlling the crystal structure of the nanoparticles and the sintering process parameters. Other metal nanoparticles may alternatively be used as well as combinations and alloys of metals.

Particles with a core-shell structure may also be used as sinterable fillers. The shell structure may be a coating of sinterable metal such as Au or Ag with nanoscale thickness, while the core structure is a low cost metal such as Cu or Al. One example of such a particle is Ag coated Cu particles. Upon heating, the sinterable coating layer also goes through a sintering process to form metal connections between fillers to boost the thermal conductivity. This process is also driven by surface tension, similar to sintering of pure Ag nanoparticles. Compared to pure Ag nanoparticles, these core-shell structured particles reduce the filler cost significantly due to much less usage of expensive Ag.

Performance may be balanced with cost by mixing sinterable and non-sinterable fillers in one formulation. This may lower thermal performance but also costs less.

FIG. 2 shows examples of different configurations of filler materials. A single sinterable type of metal is used in each example, although the invention is not so limited. The first filler material is made only of nanoscale sinterable nanoparticles 112, also referred to as nanoparticles, of about 1 micrometer (μm) or less in diameter. The second filler material has only microscale sinterable fillers 114, also referred to as microparticles with a diameter greater than 1 μm but less than 1000 um. This second material requires more stringent sintering conditions and a longer sintering duration to achieve the same level of sintering as the first material. This is due to the larger size of the particles which provides thus less driving force. The first filler material is more expensive due to the nanoscale size. The third filler material has a combination of both the nanoscale 112 particles and the microscale 114 particles. This combination may provide performance close to the first filler material but at a lower cost.

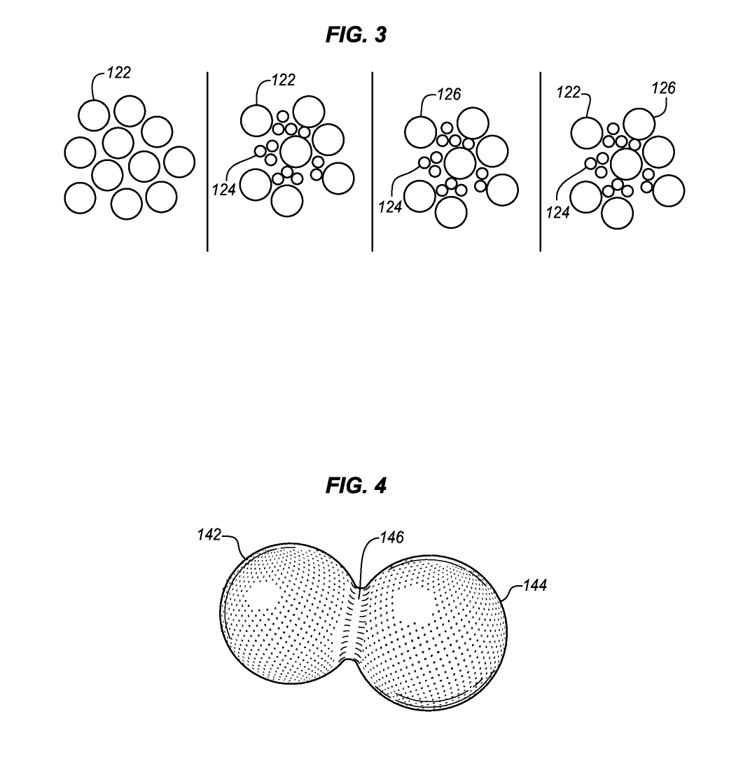

FIG. 3 depicts additional possible configurations for the filler materials with two or more metals used as filler particles. The first material has microscale particles 122 with a core-shell structure. These particles are larger than 1 μm in diameter and have a lower cost core, such as Cu, Al, and a shell with a sinterable metal, such as Au or Ag.

The second material has the same microscale fillers 122 as the first material. In addition nanoscale sinterable fillers, such as Ag or other metal nanoparticles of less than 1 μm in diameter are used to create a combination material. The third material combines nanoscale sinterable fillers 124 and microscale non-sinterable fillers 126. The microscale non-sinterable fillers may be low cost metal fillers such as Al or Cu. This combination provides a balance of thermal performance and cost. The nanoscale particles improve thermal conductivity via sintering even with the presence of non-sinterable particles. The fourth material provides a combination of all three particle types 122, 124, 126 in one material. This is a combination of three types of fillers: microscale non-sinterable low cost fillers; nanoscale sinterable expensive fillers; core-shell structured fillers. The fourth material provides better performance than the third material at lower cost than the second material.

As mentioned above, at least some of the metal particles are in the form of small particles. The particles may be, for example, in a microparticle range from about 1 μm to about 1000 μm in overall diameter. Smaller nanoparticles are easy to disperse in the polymer matrix and sinter more quickly, however, smaller nanoparticles take longer to form into significant lengths. On the other hand, the larger nanoparticles require a higher and longer heat for sintering.

As the sintering begins, there is an initial stage during which neck formation occurs. FIG. 4 is a drawing in which a first metal particle 142 and a second metal particle 144 are sintered by forming a neck 146. The neck between the filler particles is formed by diffusion and is composed of the same material as the particles. For TIM applications, the initial stage neck formation increases the modulus, but the modulus is still compliant enough for TIM application. For some types of metal particles under certain conditions, the full sintering occurs at a final stage. The TIM modulus increases significantly with the degree of sintering. The lower modulus allows the PTIM to absorb thermal and mechanical stress in the package. The degree of sintering can be controlled by controlling the metal crystal structure in the nanoparticles and by controlling the sintering process parameters such as temperature, time and filler concentration.

The dispersant may be used to keep the metal particles from sintering before reaching the curing and sintering temperatures Without a dispersant, some metal nanoparticles such as Au or Ag nanoparticles start sintering even at room temperature. The composition of the dispersant may be selected to control the sintering temperatures. In addition, function of the dispersant is eliminated during the sintering process. This may happen through evaporation or through decomposition. A variety of dispersants may be used such as long chain fatty acids (stearic acid, oleic acid, palmitic acid, etc.), and alcohols with long chain CH₂ groups (1-dodecanol, 1-decanol, etc.), among others.

The polymer matrix provides adhesion. With no die back side metallization on die side and non-sinterable metal on the lid side, metal bonding cannot be formed at both interfaces. The desired adhesion between the die and the lid surfaces is provided at least in part by the polymer matrix. The polymer matrix also affects the cured modulus of the resulting PTIM. A low modulus allows the cured matrix to absorb the thermal mechanical stress. A silicone based polymer matrix is a suitable material in many applications because it can reach a very low modulus (e.g. below 10 MPa).

A silicone matrix may be a siloxane crosslinked from silicone resin. Some example silicone resins for some embodiments include vinyl siloxanes, hydrosilicones and catalyst. Vinyl siloxanes are vinyl terminated or vinyl functional siloxanes. They may be used as the main component in a silicone matrix formulation. Hydrosilicones are siloxanes with —Si—H functional groups. Depending on the number of —Si—H functional groups, hydrosiloxane chains include both chain extenders (bi-functional) and crosslinkers (multi-functional). The catalyst may be Pt based, which can catalyze the hydrosilylation reactions between vinyl siloxanes and hydrosilicones to achieve the desired mechanical properties. Adhesion promoters, such as epoxy-containing silanes, are also added into the silicone resins to promote adhesion at die and lid interfaces.

The TIM described herein may be made by combining a filler paste and a silicone resin. The filler paste may be in the form of a paste that includes metal fillers, both sinterable and non-sinterable may be included in different sizes, and dispersants. The silicone resin may be a mixture of vinyl siloxanes, hydrosilicones and catalyst. These may be mixed in a weight ratio of 85-95% filler paste to 2-15% silicone resin.

Several examples have been developed and tested for performance as an enhanced TIM.

### Example 1: Thin BLT (40 μm) for Single Die High End Desktop Package

TABLE 1

| | PTIM | | PTIM with sintered Ag | |
|---|---|---|---|---|
| thermal resistance | 0.10 | cm²-° C./W | 0.03~0.04 | cm²-° C./W |
| (R) | | | | |
| bulk resistance | 0.07~0.08 | cm²-° C./W | 0.01 | cm²-° C./W |
| (R_{bulk}) | | | | |
| interface resistance | 0.02~0.03 | cm²-° C./W | 0.02~0.03 | cm²-° C./W |
| (Rᵢₙₜ) | | | | |
| K bulk | 4~5 | W/mK | 40 | W/mK |

As shown in Table 1, current PTIM materials have a thermal resistance (R) which has a contribution from the bulk resistance (R_{bulk}) and from the interface resistance (Rᵢₙₜ). The bulk thermal resistance depends on the thickness of the bond line so that R_{bulk}=BLT/K_{bulk}, where K_{bulk} is the bulk thermal conductivity. The K_{bulk} is about 4-5 W/mK.

With a sinterable metal filler K_{bulk} is much higher than without the sinterable fillers. K_{bulk} may not be as high as bulk metal (for example, 400 W/mK for Ag), but 40 W/mK is achievable. The interface thermal resistance Rᵢₙₜ is similar to that of a current PTIM. As a result, the total thermal resistance of the new TIM described herein is much lower and less than half the thermal resistance of a current PTIM. In addition, a package using the new TIM shows more uniform Rjc (Junction-to-Case Thermal Resistance) distribution at different locations on a die (center, corner, off-center) due to the high K_{bulk} of the TIM.

### Example 2: Thick BLT (290 μm) for Multichip Server Package

TABLE 2

| | PTIM | | PTIM with sintered Ag | |
|---|---|---|---|---|
| thermal | 0.6 | cm²-° C./W | 0.1 | cm²-° C./W |
| resistance | | | | |
| (R) | | | | |
| bulk | 0.01 × 290 | um/5 W/mK | 0.01 × 290 | um/40 W/mK |
| resistance | | | | |
| (R_{bulk}) | | | | |
| interface | 0.02~0.03 | cm²-° C./W | 0.02~0.03 | cm²-° C./W |
| resistance | | | | |
| (Rᵢₙₜ) | | | | |
| K bulk | 4~5 | W/mK | 40 | W/mK |

For a multichip package, such as one for server processors, there may be a 250 μm variation in the heights of the dies. For the heat spreader to thermally connect to both dies, the TIM must be that height. Adding in a 40 μm thickness to that yields a 250 μm+40 μm=290 μm total BLT. As shown in Table 2 for this thick BLT example, the bulk thermal resistance matters more than the interface thermal resistance. As a result, the new sinterable TIM described herein has a bigger performance lead.

FIG. 5 is a process flow diagram of forming a package using the described sinterable PTIM. First at 152 a semiconductor die is attached to a substrate. The die may be of any type that generates heat in use. There may be many dies or a single die. There may also be passive electrical components and other connectors. The die may be attached using a wire lead, flip chip, surface mount or any other desired technique. The attached die may be placed in a solder reflow furnace to solder all of the lands on the die to pads on the package substrate. The solder reflow furnace is hot enough to reflow the solder without harming the die or the substrate and may be in the range of between 180° C. and 350° C.

At 154 after the die is attached, then a thermal interface material (TIM) is applied to the die. The TIM, as described herein, includes metal nanoparticles, a dispersant, and a polymer matrix. The TIM may be applied by dispensing, by jet, or by a tape. After the TIM is applied, then at 156 a heat spreader is attached to the thermal interface material over the die and over the substrate, to thermally and/or mechanically couple the heat spreader to the die.

With the heat spreader over the one or more dies and with the TIM between the dies and the heat spreader, the combined components are heated at 158. The heating of the substrate, the die, the TIM and the heat spreader has the effect of sintering and curing the thermal interface material. The heat is applied until the TIM has been sintered and cured. This is done at a temperature below the solder reflow furnace temperature and typically at about 180° C. The actual temperature depends on the duration of the sintering and the type of metal nanoparticles, among other factors and may be as low as 120° C. and as high as 250° C. in some embodiments.

FIG. 6 is a diagram of the metal nanoparticles in the TIM. In a first view 162 the metal particles are not connected but do have some physical contact. This allows the particles to conduct heat and electricity in an inconsistent and diffuse way. In a second view 164, the TIM is sintered and cured. The metal particles are connected in the manner shown in FIG. 4. This metal bonding greatly increases the heat conduction and reduces the thermal resistance of the TIM as described above.

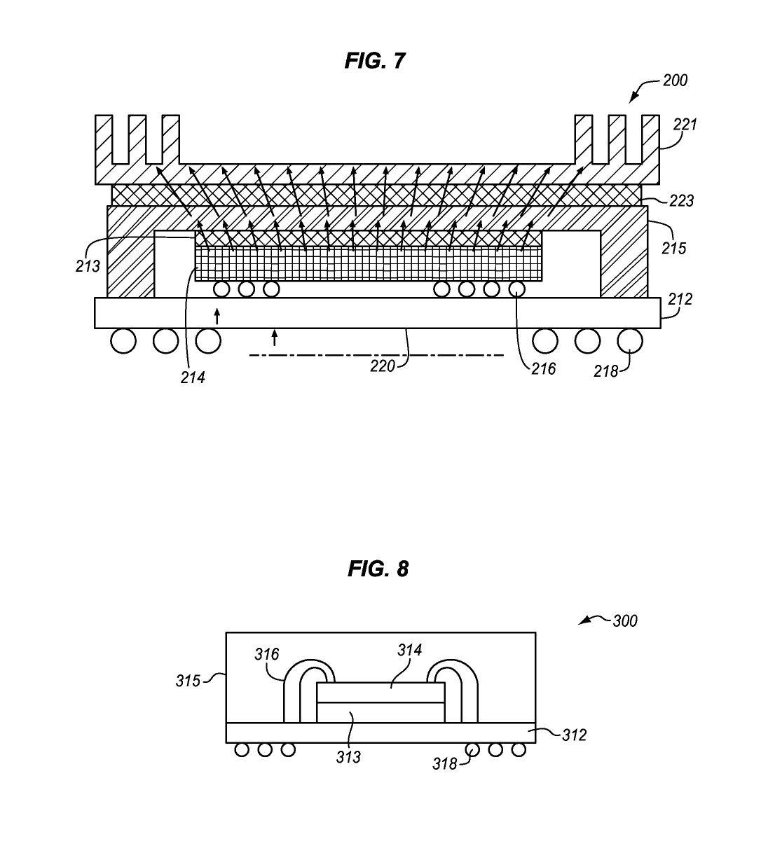

FIG. 7 is a cross-sectional side view diagram illustrating an integrated circuit package 200 in which one embodiment of the invention can be practiced. In one embodiment, the integrated circuit package 200 includes a dielectric substrate 212 with conductive paths that are electrically coupled to an integrated circuit 214, such as a semiconductor die, by solder bumps 216 used in a process commonly referred to as controlled collapsed chip connection (C4). A curable TIM 213, such as the PTIM described herein, is used as a thermal material between the integrated circuit or die 214 and an integrated heat spreader (IHS) 215.

The integrated circuit package 200 may include a plurality of solder balls 218 that are attached to a bottom surface 220 of the substrate 212. The solder balls 218 may be reflowed to attach the integrated circuit package 200 to a printed circuit board (not shown). The substrate 212 may contain routing traces, surface pads, power/ground planes and vias, etc., which electrically connect the solder balls 218 with the solder bumps 216. Although solder balls 218 are shown and described any of a variety of other connection may be used including pins, lands and pad.

The integrated circuit 214 generates heat, which is removed from the integrated circuit package 200 through the IHS. The IHS 215 is thermally coupled to the integrated circuit 214 by the PTIM 213 to absorb heat from the integrated circuit 214 and spread it across the larger surface of the IHS. The heat spreader 215 may comprise metal and metal alloys optionally with a coating of another metal or may comprise a thermally conductive composite material. The PTIM 213 is between the integrated circuit 214 and the heat spreader 215 to connect the two pieces together, to absorb mechanical stress from thermal cycling and to conduct heat.

A heat sink 221 may be attached to the heat spreader 215 to enhance heat removal. In the illustrated example, the heat sink is a metal plate with a plurality of fins, however, liquid coolers, heat pipes, or larger plates may be used. To decrease the thermal impedance between the IHS 214 and the heat sink 221, another thermal interface material 223 is applied and placed between the IHS 215 and the heat sink 221. This thermal interface material 223 may be the same or different from the PTIM 213 that is in contact with the die. Other suitable materials may include a thermal grease and a phase change material depending on the nature of the heat sink. The arrows show the flow of heat from the die, through the PTIM to the IHS and then from the IHS, through the TIM to the heat sink. In another embodiment, a wire-bonded die may require such TIM at the bottom, between the die and substrate or between the die and an insulator sitting onto a heat spreader. One of the key features of the design here is that the proposed TIM will always be on the side of the die that is opposite to that of the interconnects. Thus, in flip chip die, interconnects will be at the bottom and TIM will be on top of the die, whereas in wire-bonded die, the wire leads would be bonded on top surface of the die pads, and the TIM will be on bottom surface. Increasing the thermal conductivity of the thermal interface materials increases the rate of heat flow and allows the die to operate at a lower temperature. Heat also typically flows from the die 214 through the solder bumps 216 into the substrate 212. This substrate may have metal heat conducting layers to remove heat from the package. Heat will also flow from the substrate through the solder balls 218 into the socket or system board (not shown) to which the package is attached.

The package 200 is shown as an example. A variety of other simpler or more complex packages may be used. There may be more or fewer dies in the package and more or fewer substrates including translation and interposer substrates. The package may be designed for or include a socket or attach directly to a system board or other surface. The dies may be flipped, upright, or placed in any other position. While the application refers to a semiconductor die, a micromechanical, or optical die may be used instead. The die may be silicon, ceramic, lithium niobate, gallium arsenide, or any other material or combination thereof. While the heat spreader is shown as surrounding and sealing the die against the package substrate, it may take other forms and may expose a portion of the die to ambient or another controlled environment.

To assemble the package as described above, a grid of C4 pads are pasted to the substrate 212 and the die 214 is placed onto the solder pads 216. The assembly is passed through a solder reflow furnace to melt the C4 pads and establish a solder connection between the die and the substrate. A PTIM 213 is applied to the die 214 and the assembly is passed through the curing oven to cure the PTIM and bond the die to the heat spreader. PTIM or another adhesive may also be applied where the heat spreader contacts the package. In some cases a dielectric adhesive may be preferred. The finished package may then be attached to a printed circuit board or a socket or any other device with solder balls or a fixture. The heat sink may be attached with an adhesive TIM or a mechanical clamp or in any of a variety of other ways depending on the particular implementation.

FIG. 8 is a cross-sectional side view diagram of an alternative package configuration 300. An integrated circuit die 314 is attached to a dielectric substrate 312 using a thermal interface material 313 with sintered filler particles. The die is mounted with the back side facing down and the front side facing up so that connecting pads, lands or other terminals are facing up. The die is electrically coupled to the substrate using wire leads 316 connected to the front side terminals at one end and coupled to lands or pads on the substrate at the other end. The substrate includes internal redistribution and routing layers (not shown) to connect the wire leads to a solder ball array 318. The solder ball array is used to attach the package to a system board, motherboard, or socket (not shown). The substrate and die may be covered with an encapsulant, such as a molding compound, silicone, or other dielectric to protect the wire leads and the die. In other embodiments, the wires and die are not covered.

In operation the integrated circuit die 314 generates heat which is conducted through the back side of the die and the TIM 313 into the package substrate 312. A variety of different techniques may be used to encourage heat conduction through the die into the TIM. Similarly, a variety of different techniques may be used to remove heat from the substrate. These techniques may include conduction through the solder balls 318 into a socket or system board or both. The socket and system board may also have cooling systems to remove heat that is conducted through the solder balls.

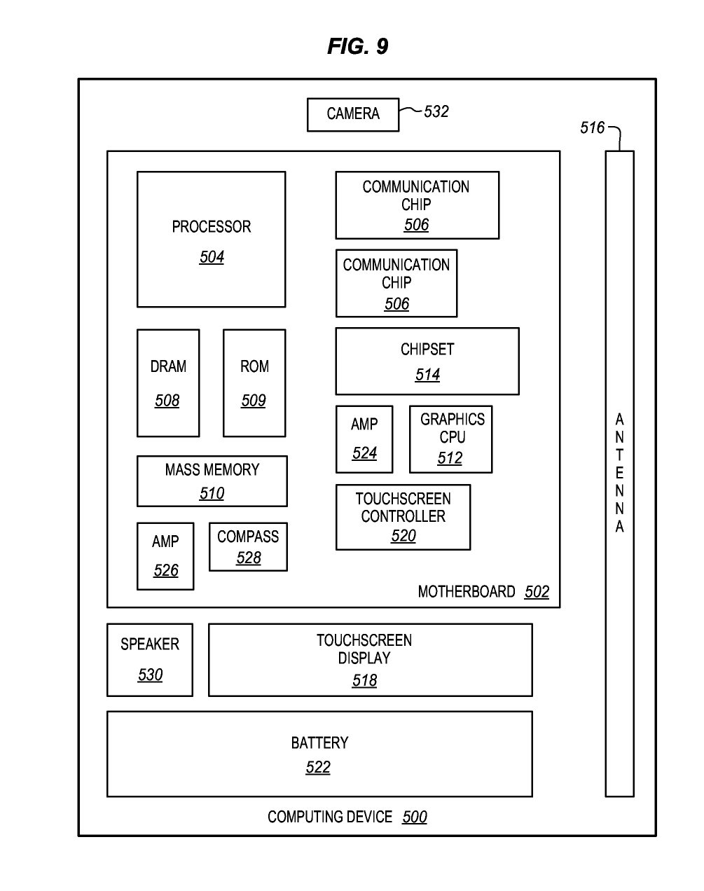

FIG. 9 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM) 508, non-volatile memory (e.g., ROM) 509, flash memory (not shown), a graphics processor 512, a digital signal processor (not shown), a crypto processor (not shown), a chipset 514, an antenna 516, a display 518 such as a touchscreen display, a touchscreen controller 520, a battery 522, an audio codec (not shown), a video codec (not shown), a power amplifier 524, a global positioning system (GPS) device 526, a compass 528, an accelerometer (not shown), a gyroscope (not shown), a speaker 530, a camera 532, and a mass storage device (such as hard disk drive) 510, compact disk (CD) (not shown), digital versatile disk (DVD) (not shown), and so forth). These components may be connected to the system board 502, mounted to the system board, or combined with any of the other components.

The communication chip 506 enables wireless and/or wired communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor, memory devices, communication devices, or other components include one or more dies that are packaged using a PTIM as described herein. The term “processor” may refer to any device or portion of a device that processes electronic data from registers and/or memory to transform that electronic data into other electronic data that may be stored in registers and/or memory.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Embodiments may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to a polymer thermal interface material (PTIM) that includes sinterable thermally conductive filler particles, a dispersant, and a silicone polymer matrix,

In further embodiments the particles comprises nanoparticles having an average particle size less than 1 micrometer.

In further embodiments the particles further comprise microparticles having an average particle size less than 30 micrometers.

In further embodiments the particles comprise a metal selected from the group consisting essentially of silver, gold, copper, and their mixtures, and silver coated copper, gold coated copper, silver coated aluminum, gold coated aluminum and their mixtures.

In further embodiments the particles comprise a metal selected from the group consisting essentially of indium, indium-silver alloy, indium-tin alloy, tin-bismuth alloy, tin-zinc alloy, tin-antimony alloy, tin-indium-bismuth alloy, gallium, gallium-tin-indium alloy, gallium-indium-tin-zinc alloy, indium-bismuth alloy, and their mixtures.

Further embodiments include non-sinterable particles being not sinterable below 200° C.

In further embodiments the non-sinterable particles comprise a material selected from a group consisting essentially of aluminum, aluminum oxide, zinc oxide, aluminum nitride, and boron nitride.

In further embodiments the particles are between 50 and 90 percent of the PTIM by volume.

In further embodiments the dispersant comprises a material selected from the group consisting essentially of long fatty chain acids, amines, alcohols, and thiols.

In further embodiments the polymer matrix includes a silicone polymer comprising vinyl groups, a silicone polymer comprising Si—H groups, and a catalyst for a curing reaction.

In further embodiments the PTIM is sintered by heating so that at least some of the particles become connected by sintering.

In further embodiments the PTIM is sintered at a temperature below a solder reflow furnace temperature.

In further embodiments the PTIM is sintered at a temperature below 200° C.

In further embodiments the polymer matrix is cured during the sintering.

Some embodiments pertain to a semiconductor package that includes a semiconductor die, a heat spreader coupled to the die, and a thermal interface material between the die and the heat spreader to mechanically and thermally couple the heat spreader to the die, the thermal interface material having sinterable thermally conductive filler particles, a dispersant, and a silicone polymer matrix.

In further embodiments the particles comprise nanoparticles having an average particle size less than 1 micrometer and microparticles having an average particle size less than 30 micrometers.

In further embodiments the particles are between 50 and 90 percent of the thermal interface material by volume.

Some embodiments pertain to a method of forming a semiconductor package that includes attaching die to substrate, applying a thermal interface material to a semiconductor, the thermal interface material comprising sinterable thermally conductive filler particles, a dispersant, and a silicone polymer matrix, attaching a heat spreader to the thermal interface material over the die to mechanically and thermally couple the heat spreader to the die, and heating the die, the thermal interface material, and the heat spreader to sinter the thermal interface material.

In further embodiments heating the thermal interface material comprises curing the polymer matrix.

In further embodiments applying the thermal interface material comprises dispensing the material over the die using a paste dispenser.

1. A polymer thermal interface material (PTIM) comprising:
sinterable thermally conductive filler particles;
a dispersant; and
a silicone polymer matrix.

2. The PTIM of claim 1, wherein the particles comprises nanoparticles having an average particle size less than 1 micrometer.

3. The PTIM of claim 2, wherein the particles further comprise microparticles having an average particle size less than 30 micrometers.

4. The PTIM of claim 1, wherein the particles comprise a metal selected from the group consisting essentially of silver, gold, copper, and their mixtures, and silver coated copper, gold coated copper, silver coated aluminum, gold coated aluminum and their mixtures.

5. The PTIM of claim 1, wherein the particles comprise a metal selected from the group consisting essentially of indium, indium-silver alloy, indium-tin alloy, tin-bismuth alloy, tin-zinc alloy, tin-antimony alloy, tin-indium-bismuth alloy, gallium, gallium-tin-indium alloy, gallium-indium-tin-zinc alloy, indium-bismuth alloy, and their mixtures.

6. The PTIM of claim 1, the particles further comprising non-sinterable particles being not sinterable below 200° C.

7. The PTIM of claim 6, wherein the non-sinterable particles comprise a material selected from a group consisting essentially of aluminum, aluminum oxide, zinc oxide, aluminum nitride, and boron nitride.

8. The PTIM of claim 1, wherein the particles are between 50 and 90 percent of the PTIM by volume.

9. The PTIM of claim 1, wherein the dispersant comprises a material selected from the group consisting essentially of long fatty chain acids, amines, alcohols, and thiols.

10. The PTIM of claim 1, wherein the polymer matrix comprises:
a silicone polymer comprising vinyl groups;
a silicone polymer comprising Si—H groups; and
a catalyst for a curing reaction.

11. The PTIM of claim 1, wherein the PTIM is sintered by heating so that at least some of the particles become connected by sintering.

12. The PTIM of claim 11, wherein the PTIM is sintered at a temperature below a solder reflow furnace temperature.

13. The PTIM of claim 11, wherein the PTIM is sintered at a temperature below 200° C.

14. The PTIM of claim 11, wherein the polymer matrix is cured during the sintering.

15. A semiconductor package comprising:
a semiconductor die;
a heat spreader coupled to the die; and
a thermal interface material between the die and the heat spreader to mechanically and thermally couple the heat spreader to the die, the thermal interface material having sinterable thermally conductive filler particles, a dispersant, and a silicone polymer matrix.

16. The semiconductor package of claim 15, wherein the particles comprise nanoparticles having an average particle size less than 1 micrometer and microparticles having an average particle size less than 30 micrometers.

17. The semiconductor package of claim 15, wherein the particles are between 50 and 90 percent of the thermal interface material by volume.

18. A method of forming a semiconductor package comprising:
attaching die to substrate;
applying a thermal interface material to a semiconductor, the thermal interface material comprising sinterable thermally conductive filler particles, a dispersant, and a silicone polymer matrix;
attaching a heat spreader to the thermal interface material over the die to mechanically and thermally couple the heat spreader to the die; and
heating the die, the thermal interface material, and the heat spreader to sinter the thermal interface material.

19. The method of claim 18, wherein heating the thermal interface material comprises curing the polymer matrix and sintering at least some of the filler particles.

20. The method of claim 18, wherein applying the thermal interface material comprises dispensing the material over the die using a paste dispenser.
